(19) United States
(12) Patent Application Publication
(10) Pub. No.: US 2008/0160707 A1
(43) Pub. Date: Jul. 3, 2008

(54) METHOD FOR FABRICATING SESMICONDUCTOR DEVICE

(76) Inventor: Jin Hyo JUNG, Boocheon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/964,175

(22) Filed: Dec. 26, 2007

(30) Foreign Application Priority Data
Dec. 27, 2006 (KR) 10-2006-0134622

(51) Int. Cl. H01L 21/336

(52) U.S. Cl. 438/297; 257/E21.409

(57) ABSTRACT

A method for fabricating a semiconductor device is provided. The method includes forming a trench having a predetermined depth in a substrate having an active area and an isolation area by selectively removing the isolation area, forming a well region in the active area of the substrate using the trench as a photo key pattern, forming an isolation layer in the trench by filling the trench with an insulating layer, forming a gate insulating layer on a portion of the well region, forming a gate electrode on the gate insulating layer; and forming a source/drain impurity area on the substrate at both sides of the gate electrode.

### RELATED APPLICATIONS

The present application claims the benefit of priority under 35 U.S.C. 119 to Korean Patent Application No. 10-2006-0134622, filed on Dec. 27, 2006, the entire contents of which are incorporated herewith by reference.

### BACKGROUND

The present invention relates to a method for fabricating a semiconductor device.

In general, when forming a semiconductor device on a substrate, an isolation process may be performed first. For instance, the isolation process may include a local oxidation of silicon (LOCOS) isolation process, which selectively performs a thermal oxidation process.

Bird's beaks are often formed at the opposite ends of a LOCOS isolation layer during the formation of the LOCOS isolation layer. Such bird's beaks may influence the operation of the semiconductor device.

Although the bird's beaks have no significant influence on a high voltage device or a high power device, however, such devices often include logic components operating at a relatively lower voltage, the operation of which may be influenced by the existence of the bird's beaks. In order to reduce the design rule for low voltage logic components, the LOCOS isolation process may be used for forming the low voltage logic components, so as to prevent the formation of bird's beaks.

In order to reduce the design rule of semiconductor technology below 0.25 μm, a shallow trench isolation (STI) process may be performed instead of the LOCOS isolation process.

However, the STI process may have drawbacks. Since a process for forming a high voltage n-well and a high voltage p-well must be performed before forming an active area, when a patterning process for forming the high voltage n-well and p-well is performed, a photo key pattern for aligning must be previously formed. Accordingly, an additional process for forming the photo key pattern must be performed. The fabricating cost is thus increased.

Alternatively, however, after forming the active area and an insulating layer, and after planarizing the active area and the insulating layer through a chemical mechanical polishing (CMP) process, the patterning process relative to the high voltage n-well and p-well may be performed by using a specific isolation layer region pattern as the photo key pattern. Thus, the additional process for forming the photo key pattern may be omitted. Thus, the fabricating cost can be reduced.

However, as discussed above, since the process for forming the high voltage wells is performed after forming the active area and performing the CMP process, the active area, which is already formed through a high temperature drive-in process for forming the high voltage wells, may be directly exposed. Because the thermal expansion coefficient of the active area is different from that of an insulating layer in an STI area, an extreme stress exists at the border surface between the active area and the STI area. That is, the extreme stress exists in sidewalls and corners of the STI area. The stress may increase as the temperature increases.

Accordingly, a defect caused by an STI dislocation may occur in the active area directly exposed in the high temperature drive-in process, especially at the sidewalls and corners of the STI area, which generate an extreme heat stress, thereby degrading the production yield and the reliability of the semiconductor device.

### SUMMARY

Embodiments consistent with the present invention provide a method for fabricating a semiconductor device. The method is capable of reducing the fabricating cost, and improving the production yield and the reliability of the semiconductor device. By omitting a process for forming a photo key pattern, a defect due to an STI dislocation may be prevented from occurring.

In one embodiment, the method The method includes forming a trench having a predetermined depth in a substrate having an active area and an isolation area by selectively removing the isolation area, forming a well region in the active area of the substrate using the trench as a photo key pattern, forming an isolation layer in the trench by filling the trench with an insulating layer, forming a gate insulating layer on a portion of the well region, forming a gate electrode on the gate insulating layer; and forming a source/drain impurity area on the substrate at both sides of the gate electrode.

In one embodiment, the method includes sequentially forming a pad oxide layer and a nitride layer on a substrate having an active area and an isolation area, selectively removing the nitride layer formed in the isolation area, forming a well region in the active area by using a portion of the selectively removed nitride layer as a photo key pattern, forming a trench having a predetermined depth by selectively removing the pad oxide layer and a portion of the substrate using the nitride layer as a mask, forming an isolation layer in the trench by filling the trench with an insulating layer, forming a gate insulating layer on a portion of the well region, forming a gate electrode on the gate insulating layer, and forming a source/drain impurity area on the substrate at both sides of the gate electrode.

### BRIEF DESCRIPTION OF THE DRAWING

FIGS. 1A through 1E are sectional views showing a method for fabricating a semiconductor device according to an embodiment consistent with the present invention; and

FIGS. 2A through 2F are sectional views showing a method for fabricating a semiconductor device according to another embodiment consistent with the present invention.

### DETAILED DESCRIPTION

Any reference in this specification to “one embodiment, ” “an embodiment,” “example embodiment,” etc., means that a particular feature described in connection with the “embodiment” is included in at least one embodiment consistent with the invention. The appearances of such phrases in various places in the specification are not necessarily all referring to the same embodiment. Further, when a particular feature is described in connection with any embodiment, it is within the purview of one skilled in the art to effect such feature in connection with other possible embodiments.

Hereinafter, a method for fabricating a semiconductor device according to an embodiment consistent with the present invention will be described in detail with reference to the accompanying drawings.

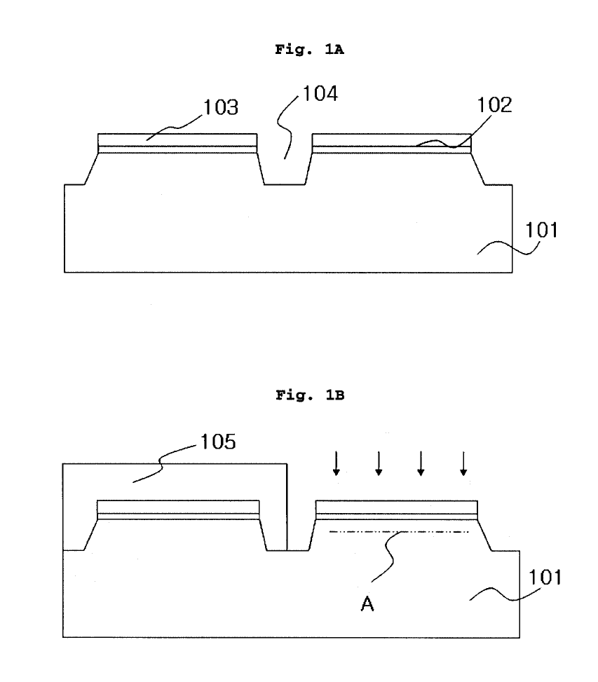

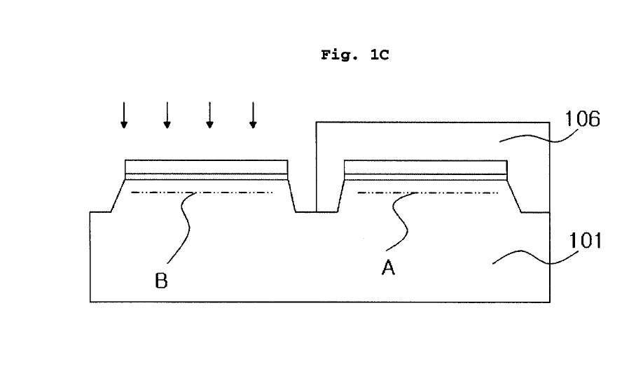

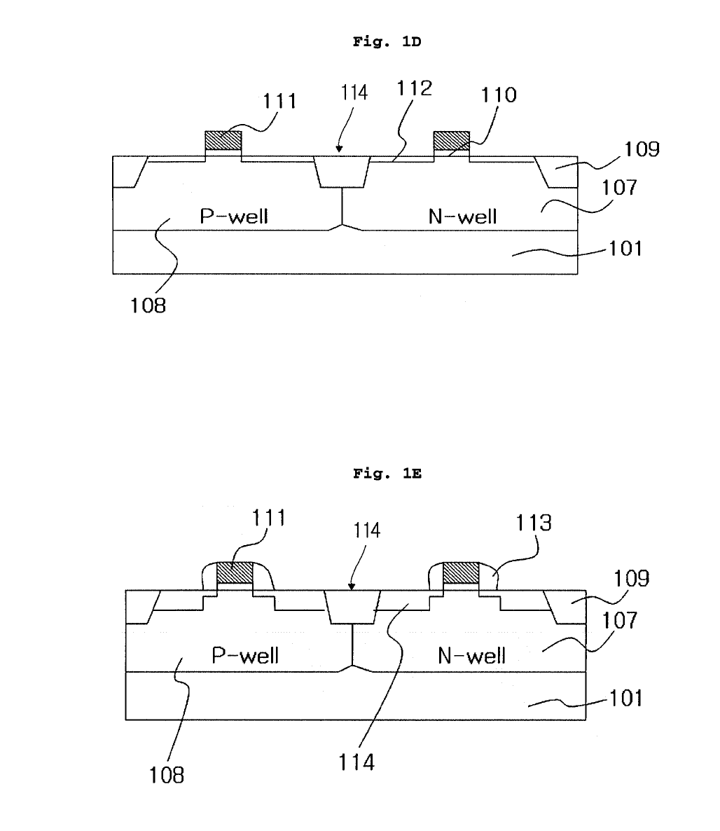

Referring to FIG. 1A, a pad oxide layer 102 and a nitride layer 103 are sequentially formed on the entire surface of a substrate 101. Pad oxide layer 102 and nitride layer 103 are selectively removed through a photo lithography process and an etching process, thereby defining an isolation area exposing a portion of substrate 101.

Thereafter, the exposed portion of substrate 101 is selectively removed by using the remaining pad oxide layer 102 and nitride layer 103 as a mask, thereby forming a trench 104 having a predetermined depth.

Referring to FIG. 1B, after coating a first photoresist 105 on substrate 101 having trench 104, first photoresist 105 is patterned through an exposure and development process, thereby defining a high voltage n-well region.

Subsequently, n-type impurity ions A may be implanted into substrate 101 by using the patterned first photoresist 105 as a mask.

Referring to FIG. 1C, first photoresist 105 is thereafter removed. Then, after coating a second photoresist 106 on substrate 101, second photoresist 106 is patterned through an exposure and development process, thereby defining a high voltage p-well region.

Then, p-type impurity ions B may be implanted into substrate 101 by using the patterned second photoresist 106 as a mask.

Referring to FIG. 1D, second photoresist 106 is thereafter removed. Then, a drive-in process is performed to substrate 101 in order to diffuse n-type impurity ions A and p-type impurity ions B into substrate 101, thereby forming an n-well region 107 and a p-well region 108.

Subsequently, a gap-fill insulating layer (not shown) may be formed on the entire surface of substrate 101 including trench 104. Then, pad oxide layer 102 is polished to form an isolation layer 109 in trench 104.

Thereafter, gate electrodes 111 are formed on p-well region 108 and n-well region 107 of substrate 101. Gate insulating layers 110 are formed between gate electrodes 111 and n-well region 107 or p-well region 108.

P-type and n-type impurity ions may be implanted respectively into n-well region 107 and p-well region 108 by using gate electrodes 111 as a mask, thereby forming a lightly doped drain (LDD) region 112.

Referring to FIG. 1E, an insulating layer (not shown) may be formed on the entire surface of substrate 101. Then, an etchback process may be performed on the entire surface of the insulating layer, so that insulating sidewalls 113 are formed at both sides of gate electrodes 111.

Subsequently, p-type and n-type impurity ions may be implanted respectively into n-well region 107 and p-well region 108 of substrate 101 using insulating sidewalls 113 and gate electrodes 111 as a mask, thereby forming a source/drain impurity area 114.

Therefore, since the high voltage n-well and p-well process may be performed by using trench 104 in a certain region as a photo key pattern, an additional process of forming the photo key pattern is unnecessary. Thus, the fabricating cost can be reduced.

Next, the implanted ions may be deeply penetrated into substrate 101 by activating the ions implanted through the drive-in process. Because trench 104 is not filled with an insulating layer during the drive-in process, heat stress is rarely incurred at the sidewalls and corners of trench 104. Accordingly, a defect caused in the related art by an STI dislocation can be effectively prevented.

Meanwhile, in one embodiment, after forming trench 104, the p-well and n-well process can be performed after forming a linear oxide layer on the surface of trench 104. Alternatively, the p-well and n-well process can be performed before growing the linear oxide layer in trench 104.

In addition, after performing the p-well and n-well process and after growing the linear oxide layer on the surface of trench 104, trench 104 can be capped with the insulating layer while maintaining the linear oxide layer as is (not shown). Alternatively, trench 104 can be capped with the insulating layer after the linear oxide layer is removed.

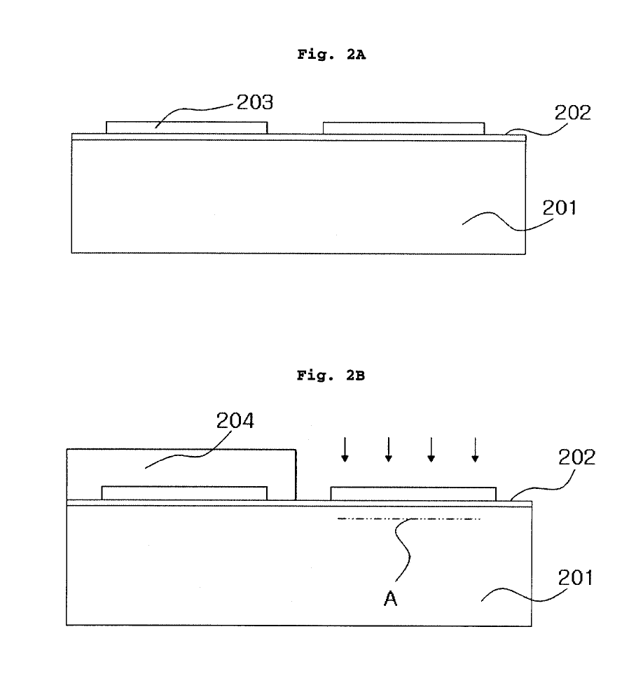

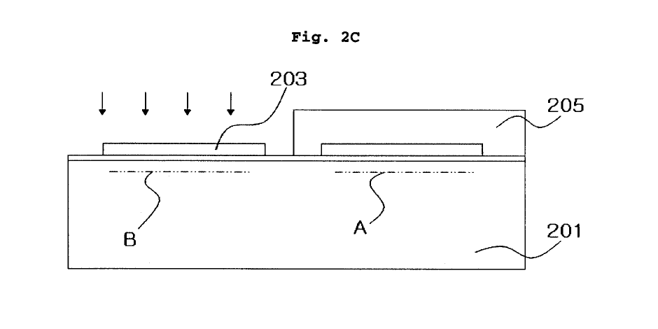

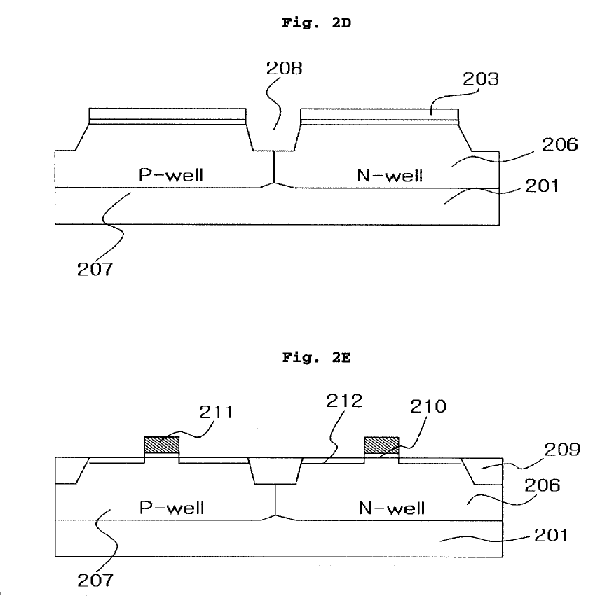

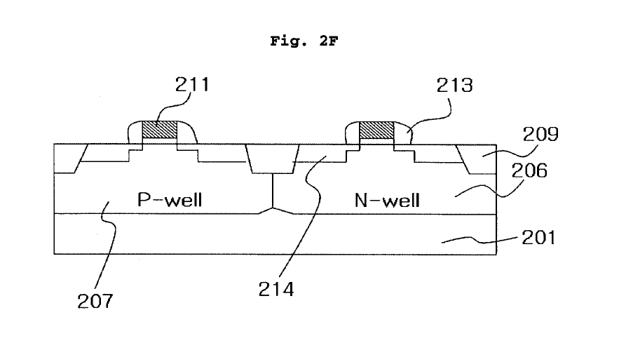

Referring to FIG. 2A, a pad oxide layer 202 and a nitride layer 203 are sequentially formed on the entire surface of a substrate 201. Nitride layer 203 may be selectively removed through a photo lithography process and an etching process, thereby defining an isolation area.

As shown in FIG. 2B, after coating a first photoresist 204 on substrate 201, first photoresist 204 is patterned through an exposure and development process, thereby defining a high voltage n-well region.

Subsequently, n-type impurity ions A may be implanted into substrate 201 by using the patterned first photoresist 204 as a mask.

Referring to FIG. 2C, first photoresist 204 is thereafter removed. Then, after coating a second photoresist 205 on substrate 201, second photoresist 205 is patterned through the exposure and development process, thereby defining a high voltage p-well region.

Then, p-type impurity ions B may be implanted into substrate 201 by using the patterned second photoresist 205 as a mask.

Referring to FIG. 2D, second photoresist 205 is thereafter removed. Then, a drive-in process may be performed to substrate 201 in order to diffuse n-type impurity ions A and p-type impurity ions B into substrate 201, thereby forming a n-well region 206 and a p-well region 207.

Then, photoresist 205 and a portion of substrate 201 are selectively removed by using nitride layer 203 as a mask, thereby forming a trench 208 having a predetermined depth.

As shown in FIG. 2E, a portion of nitride layer 203 and pad oxide layer 202 are removed, and a gap-fill insulating layer (not shown) may be formed on the entire surface of substrate 201 including trench 208. Then, pad oxide layer 202 is polished to form an isolation layer 209 in trench 208.

Thereafter, gate electrodes 211 are formed on p-well region 207 and n-well region 206 of substrate 201. Gate insulating layers 210 are formed between gate electrode 211 and n-well region 206/p-well region 207.

P-type and n-type impurity ions A and B may be implanted respectively into n-well region 206 and p-well region 207 by using gate electrodes 211 as a mask, thereby forming a lightly doped drain (LDD) region 212.

Referring to FIG. 2F, an insulating layer (not shown) may be formed on the entire surface of substrate 201. Then, an etchback process may be performed on the entire surface of the insulating layer, so that insulating sidewalls 213 are formed at both sides of gate electrodes 211.

Subsequently, p-type and n-type impurity ions A and B may be implanted respectively into n-well region 206 and p-well region 207 by using insulating sidewalls 213 and gate electrodes 211 as a mask, thereby forming a source/drain impurity area 214.

In one embodiment, since the high voltage n-well and p-well process may be performed by using nitride layer 203 as a photo key pattern, an additional process for forming the photo key pattern may be unnecessary. Accordingly, the fabricating cost can be reduced.

Next, the implanted ions may be deeply penetrated into substrate 201 by activating the implanted ions through the drive-in process (not shown). Because trench 208 is not formed during the drive-in process, an STI dislocation caused by heat stress may not be incurred.

In view of the above, the method for fabricating the semiconductor device, according to an embodiment consistent with the present invention, may have the following effects.

First, the process for forming the high voltage p-well and n-well may be performed after forming the trench. Accordingly, the fabrication process may be simplified. As a result, the fabricating cost can be reduced. In addition, the production yield and the reliability of the semiconductor device can be improved by preventing defects, such as STI dislocations, from occurring.

Second, the high voltage p-well and n-well process may be performed by using the insulating layer as the photo key pattern before forming the trench. Accordingly, the fabrication process may be simplified, thereby reducing the fabricating cost. In addition, since the trench is not formed during the drive-in process, the STI dislocation caused by the heat stress may be prevented, thereby improving the production yield and the reliability of the semiconductor device.

Although embodiments consistent with the present invention have been described in detail with reference to a number of illustrative embodiments thereof, it should be understood that numerous other embodiments can be devised by those skilled in the art without departing from the spirit and scope of appended claims. Moreover, various variations and modifications are possible in the component parts and/or arrangements of the subject combination arrangement within the scope of the appended claims. In addition to variations and modifications in the component parts and/or arrangements, alternative uses will also be apparent to those skilled in the art.

What is claimed is:

1. A method for fabricating a semiconductor device, comprising:
forming a trench having a predetermined depth in a substrate having an active area and an isolation area by selectively removing the isolation area;
forming a well region in the active area of the substrate using the trench as a photo key pattern;
forming an isolation layer in the trench by filling the trench with an insulating layer;
forming a gate insulating layer on a portion of the well region;
forming a gate electrode on the gate insulating layer; and
forming a source/drain impurity area on the substrate at both sides of the gate electrode.

2. The method of claim 1, wherein forming the trench comprises:
sequentially forming a pad oxide layer and a nitride layer on the substrate; and
selectively removing the nitride layer and the pad oxide layer through a photo lithography process and an etching process.

3. The method of claim 2, further comprising selectively removing a portion of the substrate by using the selectively removed nitride layer and the selectively removed pad oxide layer as a mask.

4. The method of claim 1, wherein forming the well region using the trench as a photo key pattern comprises:
forming a first photo key pattern by coating a first photoresist layer on the substrate and patterning the first photoresist layer;
forming a first high voltage well region by using the first photo key pattern as a mask;
forming a second photo key pattern by coating a second photoresist layer on the substrate and patterning the second photoresist layer; and
forming a second high voltage well region by using the second photo key pattern as a mask.

5. A method for fabricating a semiconductor device, comprising:
sequentially forming a pad oxide layer and a nitride layer on a substrate having an active area and an isolation area;
selectively removing the nitride layer formed in the isolation area;
forming a well region in the active area by using a portion of the selectively removed nitride layer as a photo key pattern;
forming a trench having a predetermined depth by selectively removing the pad oxide layer and a portion of the substrate using the nitride layer as a mask;
forming an isolation layer in the trench by filling the trench with an insulating layer;
forming a gate insulating layer on a portion of the well region;
forming a gate electrode on the gate insulating layer; and
forming a source/drain impurity area on the substrate at both sides of the gate electrode.

6. The method of claim 5, wherein forming the well region using the trench as a photo key pattern comprises:
forming a first photo key pattern by coating a first photoresist layer on the substrate and patterning the first photoresist layer;
forming a first high voltage well region using the first photo key pattern as a mask;
forming a second photo key pattern by coating a second photoresist layer on the substrate and patterning the second photoresist layer; and
forming a second high voltage well region by using the second photo key pattern as a mask.
